(19) United States
(12) Patent Application Publication
(10) Pub. No.: US 2026/0314025 A1
(43) Pub. Date: Oct. 8, 2026

(54) FLUORINE-CONTAINING PLASMA TREATMENT IN SEMICONDUCTOR PROCESS

(71) Applicant: TEXAS INSTRUMENTS INCORPORATED, Dallas, TX (US)

(72) Inventors: Mahalingam Nandakumar, Richardson, TX (US); Gordon Nielsen, Cedar Hills, UT (US); Isaac Curtis, Sandy, UT (US); Divya Mishra, Lehi, UT (US); Derek Robert Butcher, Salt Lake City, UT (US)

(21) Appl. No.: 19/287,316

(22) Filed: Jul. 31, 2025

Related U.S. Application Data
(60) Provisional application No. 63/783,020, filed on Apr. 3, 2025.

(51) Int. Cl. H10D 64/68; H01L 21/28; H10D 30/60; H10D 64/62; H10D 64/66

(52) U.S. Cl. CPC H10D 64/693; H10D 30/601; H10D 64/0134; H10D 64/01344; H10D 64/663; H10D 64/62

(57) ABSTRACT

The present disclosure generally relates to a fluorine-containing plasma treatment in semiconductor processing for forming a semiconductor device. In an example, a semiconductor device includes a semiconductor substrate, a gate dielectric layer over the semiconductor substrate, and a gate electrode over the gate dielectric layer. The gate dielectric layer includes nitrided silicon oxide that includes fluorine. The gate electrode includes a proximal portion proximate the gate dielectric layer, and the proximal portion of the gate electrode does not include fluorine.

### CROSS-REFERENCE TO RELATED APPLICATIONS

This application claims priority to and the benefit of U.S. Provisional Patent Application Ser. No. 63/783,020, filed on Apr. 3, 2025, which is incorporated herein by reference in its entirety.

### BACKGROUND

Integrated circuits (ICs) may include various semiconductor devices that have components formed in or on a semiconductor substrate. An approach to achieve improved performance characteristics of ICs, such as reduced power consumption and increased speed, is scaling the semiconductor devices of the ICs to smaller technology nodes. Scaling these semiconductor devices to smaller technology nodes may create challenges that may not have been previously encountered at larger technology nodes. Further, these challenges may adversely impact the performance characteristics of ICs that are sought to be improved by scaling. Hence, scaling of devices in ICs to smaller technology nodes typically requires novel approaches to semiconductor processing for fabricating those devices.

### SUMMARY

An example is a semiconductor device. The semiconductor device includes a semiconductor substrate, a gate dielectric layer over the semiconductor substrate, and a gate electrode over the gate dielectric layer. The gate dielectric layer includes nitrided silicon oxide that includes fluorine. The gate electrode includes a portion proximate the gate dielectric layer, and the portion does not include fluorine.

Another example is a method. An oxide layer is formed over a semiconductor substrate. A fluorine-containing plasma treatment is performed on the oxide layer. The oxide layer is nitrided.

A further example is a method. A gate oxide layer is formed over a semiconductor substrate. Fluorine is incorporated into the gate oxide layer including using a plasma treatment. The gate oxide layer is nitrided. A gate electrode is formed over the gate oxide layer.

A yet further example is a semiconductor device. The semiconductor device includes a semiconductor substrate, a gate dielectric layer, a gate electrode, a source/drain region, and a metal-semiconductor compound. The gate dielectric layer is over the semiconductor substrate. The gate electrode is over the gate dielectric layer. The source/drain region is in the semiconductor substrate and is laterally proximate the gate electrode. The metal-semiconductor compound is on the semiconductor substrate at the source/drain region. The metal-semiconductor compound includes fluorine.

Another example is a method. A fluorine-containing plasma treatment is performed on a semiconductor material. A metal is formed on the semiconductor material. The metal is reacted with the semiconductor material to form a metal-semiconductor compound.

A further example is a method. A gate dielectric layer is formed over a semiconductor substrate. A gate electrode is formed over the gate dielectric layer. Fluorine is incorporated into a source/drain region of the semiconductor substrate proximate the gate electrode including using a plasma treatment. A metal is formed on the source/drain region. An anneal process is performed to react the metal with a portion of the semiconductor substrate at the source/drain region.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a flow chart of a method for forming a dielectric layer including nitrogen and fluorine according to some examples.

FIG. 2 is a flow chart of another method for forming a dielectric layer including nitrogen and fluorine according to some examples.

FIGS. 3A, 3B, and 3C are charts illustrating process parameters for an example spike anneal according to some examples.

FIG. 4 is a flow chart of a method for forming a metal-semiconductor compound according to some examples.

FIGS. 5, 6, 7, 8, and 9 are respective cross-sectional views of a semiconductor device in intermediate stages of manufacturing according to some examples.

FIG. 10 is a graph illustrating fluorine profiles across a gate electrode, a gate dielectric layer, and a semiconductor substrate according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to a fluorine-containing plasma treatment in semiconductor processing for forming a semiconductor device. In some examples, a semiconductor device includes a gate dielectric layer over a semiconductor substrate and a gate electrode over the gate dielectric layer. The gate dielectric layer includes a nitrided silicon oxide that includes fluorine, and the gate electrode includes a portion proximate the gate dielectric layer that does not include fluorine. In some examples, an oxide layer is formed over a semiconductor substrate. A fluorine-containing plasma treatment is performed on the oxide layer, and the oxide layer is nitrided. The oxide layer may be a gate oxide layer, and the fluorine-containing plasma treatment may cause fluorine to be incorporated into the oxide layer. A gate electrode may be formed over the oxide layer. Such examples may achieve an improved interface between the oxide layer and the semiconductor substrate and may achieve improved mobility of carriers in, e.g., a channel region of the semiconductor device (e.g., a field effect transistor (FET)). Performance mismatch between different semiconductor devices and noise may be reduced. Other benefits and advantages may be achieved.

In some examples, a semiconductor device includes a gate dielectric layer over a semiconductor substrate, a gate electrode over the gate dielectric layer, a source/drain region in the semiconductor substrate, and a metal-semiconductor compound on the semiconductor substrate at the source/drain region. The source/drain region is laterally proximate the gate electrode. The metal-semiconductor compound and/or the semiconductor substrate near the metal-semiconductor compound include fluorine. In some examples, a fluorine-containing plasma treatment is performed on a semiconductor material (such as a semiconductor substrate). A metal is formed on the semiconductor material and is reacted, such as by an anneal process, with the semiconductor material to form a metal-semiconductor compound. The fluorine-containing plasma treatment may cause fluorine to be incorporated into the semiconductor material. The semiconductor material may be at a source/drain region in a semiconductor substrate such that the metal is formed on the source/drain region and reacts with a portion of the semiconductor substrate at the source/drain region. A gate dielectric layer may be formed over the semiconductor substrate, and a gate electrode may be formed over the gate dielectric layer, where the source/drain region is laterally proximate the gate dielectric layer and gate electrode. The fluorine incorporated into the semiconductor material may reduce metal piping into the semiconductor material when reacting the metal to the semiconductor material. Other benefits and advantages may be achieved.

Various examples are described subsequently. Although the specific examples may illustrate various aspects of the above generally described features, examples may incorporate any combination of the above generally described features (which are described in more detail in examples below).

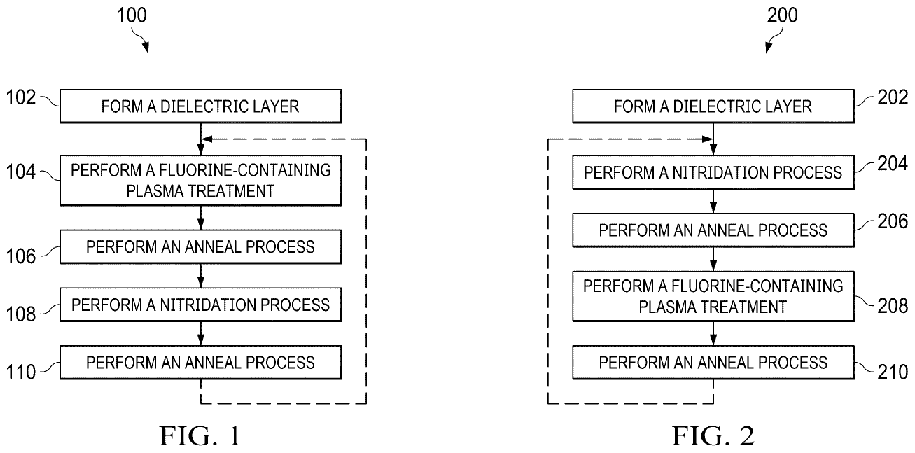

FIG. 1 is a flow chart of a method 100 for forming a dielectric layer including nitrogen and fluorine according to some examples. At block 102, a dielectric layer is formed, such as on a substrate, and more particularly, on a semiconductor substrate. In some examples, the dielectric layer is or includes an oxide, such as silicon oxide. In some examples, the dielectric layer is formed using an oxidation process on a semiconductor substrate, such as a bulk silicon substrate. The oxidation process forms an oxide layer at an upper surface of the semiconductor substrate. The oxidation process may be or include an in situ steam generation (ISSG) oxidation. The ISSG oxidation may include flowing a gas mixture including nitrous oxide (N₂O) gas and hydrogen (H₂) gas in a process chamber in which the semiconductor substrate is located. A flow rate of the nitrous oxide (N₂O) gas into the process chamber may be in a range from 5,000 standard cubic centimeters per minute (sccm) to 50,000 sccm, and a flow rate of the hydrogen (H₂) gas into the process chamber may be in a range from 50 sccm to 5,000 sccm. The ISSG oxidation may be performed at a temperature in a range from 950° C. to 1,050° C. in the process chamber. Generally, the gases flowed into the process chamber react and/or decompose such that oxygen reacts with the semiconductor material at the upper surface of the semiconductor substrate. In examples in which the semiconductor material is silicon, the ISSG oxidation forms silicon oxide. In some examples, no significant quantity of nitrogen is formed in the oxide formed at the upper surface of the semiconductor substrate by the ISSG oxidation. Nitrogen from the nitrous oxide (N₂O) gas generally does not react with the semiconductor material at the upper surface and is flowed out or purged from the process chamber. In some examples, the dielectric layer (e.g., oxide layer) has a thickness in a range from 18 Angstroms to 22 Angstroms.

At block 104, a fluorine-containing plasma treatment is performed on the dielectric layer. The fluorine-containing plasma treatment causes fluorine to be incorporated into the dielectric layer. The fluorine-containing plasma treatment does not substantially etch the dielectric layer (e.g., does not remove more than 1 Anstrom). In some examples, the fluorine-containing plasma treatment includes flowing a fluorine-containing gas at a low flow rate into a process chamber in which a plasma is generated. The fluorine-containing gas may be or include nitrogen trifluoride (NF₃) gas, dinitrogen hexafluoride (N₂F₆) gas, another fluorine-containing gas, or a combination thereof. More particularly, the fluorine-containing plasma treatment incorporates controlled amount of fluorine directly on the dielectric layer (e.g., a gate oxide layer). Further, the fluorine-containing gas including a molecular compound (e.g., NF₃, N₂F₆, or various molecules including N combined with F, C, and/or H) facilitates incorporating nitrogen into the dielectric layer while reducing nitrogen penetration into the substrate—e.g., due to reduced energy associated with nitrogen upon breaking up of the molecules. As such, the fluorine-containing plasma treatment may also include molecular nitridation or molecular nitridation treatment.

In some examples, the fluorine-containing plasma treatment includes flowing a mixture of a fluorine-containing gas and an inert gas, such as helium (He), argon (Ar), or the like. In some examples, the fluorine-containing gas is flowed at a rate from 5 sccm to 15 sccm, and the inert gas is flowed at a rate equal to or greater than 100 sccm, such as in a range from 100 sccm to 200 sccm. In some examples, the fluorine-containing plasma treatment is performed in an inductively coupled plasma (ICP) process chamber with a high pressure (e.g., equal to or greater than 50 milliTorr (mTorr)) and a low source power (e.g., equal to or less than 300 Watts (W)). A pressure of the fluorine-containing plasma treatment may be in a range from 50 mTorr to 300 mTorr. In some examples, a source power of the fluorine-containing plasma treatment may be equal to or less than 100 W. The plasma-containing plasma treatment may be isotropic, such as without a bias power.

At block 106, optionally, an anneal process is performed to anneal the dielectric layer. The anneal process may be a furnace anneal, a spike anneal, and/or a laser anneal (e.g., a flash lamp anneal or a pulsed laser anneal). The furnace anneal may include a temperature in a range from 600° C. to 800° C. An environment for the furnace anneal may be or include nitrogen (N₂) gas or another gas. Generally, a spike anneal may be performed at a peak temperature equal to or greater than 950° C., such as equal to or greater than 1,150° C., in a process chamber in which a gas mixture including nitrogen (N₂) gas and oxygen (O₂) gas is flowed. The flow rate of nitrogen (N₂) gas is much greater than a flow rate of oxygen (O₂) gas, such as in a ratio equal to or greater than 90:1 (N₂:O₂), and more particularly, in a ratio equal to or greater than 100:1 (N₂:O₂). Generally, a laser anneal (e.g., a flash lamp anneal) may reach a peak temperature equal to or greater than 1,175° C., such as in a range from 1,175° C. to 1,350° C., for a duration equal to or less than 800 milliseconds, such as in a range from 200 milliseconds to 400 milliseconds. In some examples, a laser anneal (e.g., a pulsed laser anneal) may reach a peak temperature equal to or greater than 1,175° C., such as in a range from 1,175° C. to 1,350° C., for a duration of equal to or less than 200 nanoseconds, such as in a range from 100 nanoseconds to 200 nanoseconds. The laser anneal may be performed in an ambient environment (e.g., the environment of the fab) or may be performed in, e.g., a nitrogen (N₂) environment. Other anneal processes may be implemented at block 106.

At block 108, a nitridation process is performed on the dielectric layer. The nitridation process causes the dielectric layer (e.g., oxide layer) to be nitrided or to include nitrogen. In some examples, the nitridation process is a decoupled plasma nitridation (DPN). As an example, a DPN may be performed in an ICP process chamber with flowing nitrogen (N₂) gas in a low energy plasma (e.g., equal to or less than 2 kilowatts (kW)). A duty cycle of the power (e.g., percentage of time power is on relative to total time) may be in a range from 5% to 40%. A flow rate of the nitrogen (N₂) gas in the DPN may be in a range from 100 sccm to 600 sccm. The DPN may be performed at a temperature in a range from 20° C. to 40° C. in the process chamber. The DPN may be performed at a pressure in a range from 5 mTorr to 80 mTorr, such as 20 mTorr. The DPN may be performed for a duration in a range from 20 seconds to 300 seconds. Another nitridation process may be implemented.

At block 110, a post-nitridation anneal process is performed on the dielectric layer. The post-nitridation anneal process of block 110 may be like the anneal process of block 106 described above. The post-nitridation anneal process at block 110 may restore bonds that were broken during a preceding DPN (e.g., for substitution of oxygen by nitrogen) and may drive oxygen to, e.g., an oxide-silicon interface.

The fluorine-containing plasma treatment of block 104 and the nitridation process of block 108 (individually or in combination) may be repeatedly performed any number of times, with various anneal processes performed or not performed in the iterations. For example, the fluorine-containing plasma treatment of block 104 may be added between the nitridation process of block 108 and the post-nitridation anneal process of block 110.

FIG. 2 is a flow chart of a method 200 for forming a dielectric layer including nitrogen and fluorine according to some examples. At block 202, a dielectric layer is formed, like described above at block 102 in FIG. 1. At block 204, a nitridation process is performed on the dielectric layer, like described above at block 108 in FIG. 1. At block 206, a post-nitridation anneal process is performed on the dielectric layer, like described above with respect to block 110 (and block 106) in FIG. 1. At block 208, a fluorine-containing plasma treatment is performed on the dielectric layer, like described above with respect to block 104 in FIG. 1. At block 210, an anneal process is performed on the dielectric layer, like described above with respect to block 106 in FIG. 1. The nitridation process of block 204 and the fluorine-containing plasma treatment of block 208 (individually or in combination) may be repeatedly performed any number of times, with various anneal processes performed or not performed in the iterations. For example, the fluorine-containing plasma treatment of block 208 may be performed between the nitridation process of block 204 and the post-nitridation anneal process at block 206—e.g., in addition to or in lieu of the fluorine-containing plasma treatment of block 208 as shown in FIG. 2.

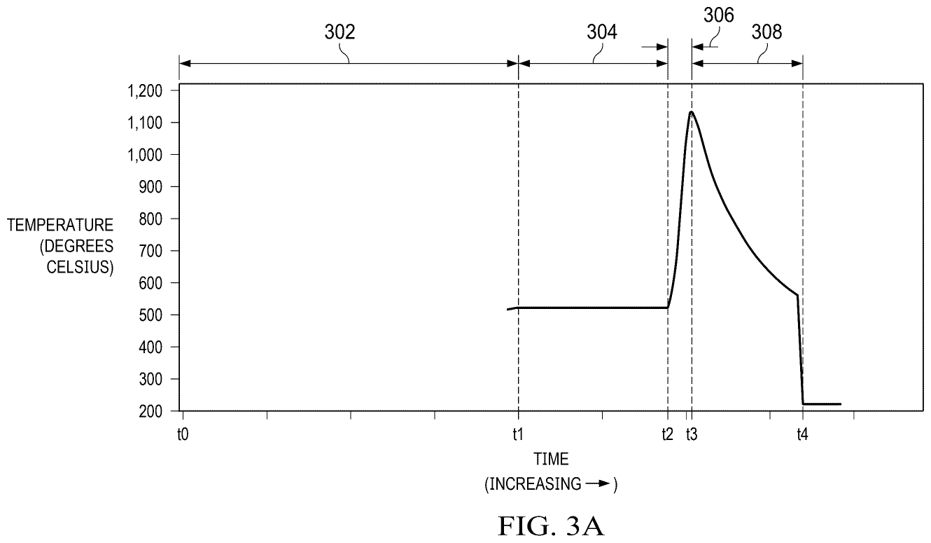

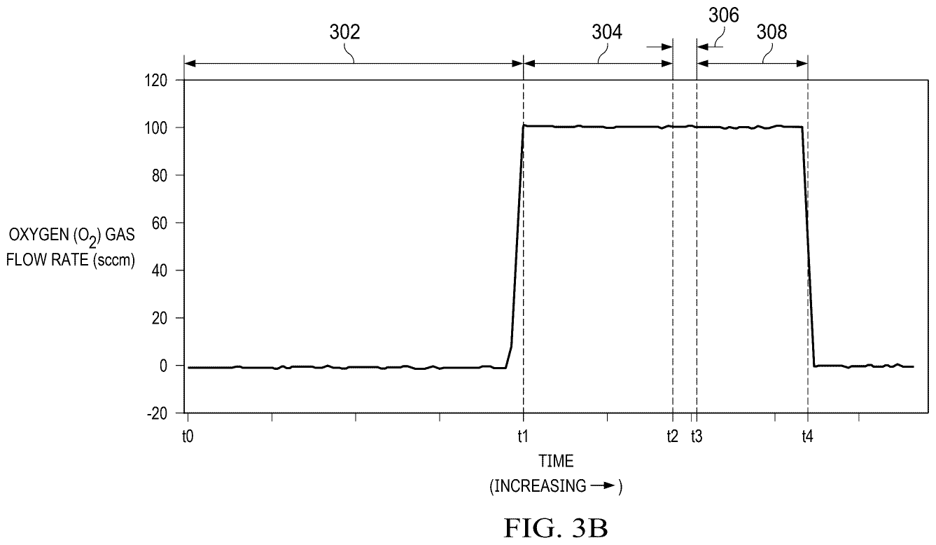

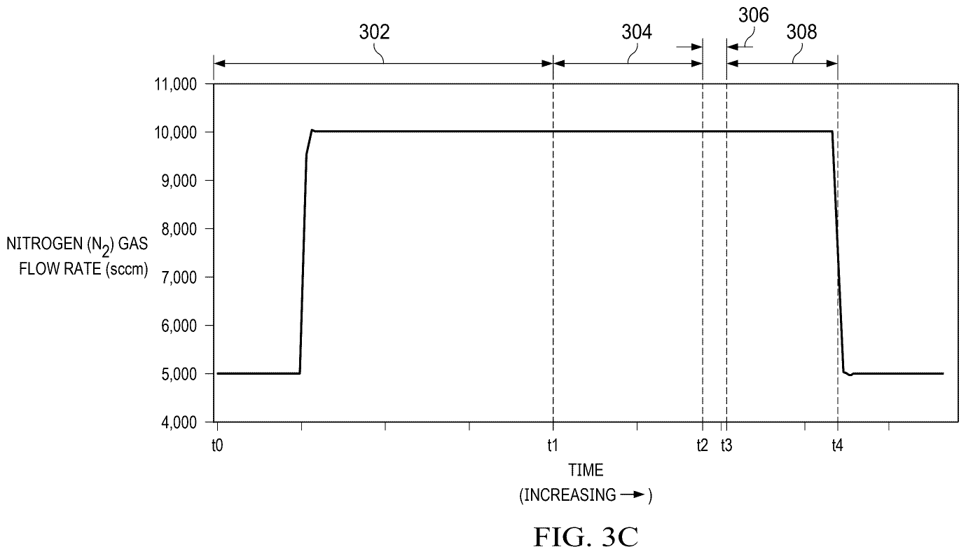

FIGS. 3A, 3B, and 3C are charts illustrating process parameters for an example spike anneal according to some examples. The spike anneal of FIGS. 3A, 3B, and 3C may be performed as the anneal process(es) of FIGS. 1 and 2. FIG. 3A shows temperature in degrees Celsius. FIG. 3B shows a flow rate of oxygen (O₂) gas in sccm. FIG. 3C shows a flow rate of nitrogen (N₂) gas in sccm. In some examples, the spike anneal is performed in a radiance chamber. The spike anneal includes a set-up period 302, a stabilization period 304, a ramp-up period 306, and a cool-down period 308.

At time t0, a semiconductor substrate with the dielectric layer formed thereon enters the process chamber, and the set-up period 302 begins and continues to time t1. The temperature during the set-up period 302 may vary, e.g., depending on requirements of the process chamber. Nitrogen (N₂) gas is flowed into the process chamber beginning at time t0 at a rate of 5,000 sccm. The nitrogen (N₂) gas flow rate is subsequently increased during the set-up period to 10,000 sccm and is maintained throughout the remaining set-up period 302, the stabilization period 304, the ramp-up period 306, and the cool-down period 308 (e.g., maintained to time t4), as shown in FIG. 3C. No oxygen (O₂) gas is flowed into the process chamber during the set-up period 302, as shown in FIG. 3B.

At time t1, the stabilization period 304 begins and continues to time t2. Throughout the stabilization period 304, the temperature is at a constant temperature in a range from 500° C. to 600° C. (e.g., approximately 525° C. as illustrated in FIG. 3A). At time t1, oxygen (O₂) gas begins to be flowed into the process chamber beginning at a rate of 100 sccm and is maintained throughout the stabilization period 304, the ramp-up period 306, and the cool-down period 308 (e.g., maintained to time t4), as shown in FIG. 3B. The stabilization period 304 stabilizes the environment (e.g., including the gas flow rates) in the process chamber for performing the spike anneal.

At time t2, the ramp-up period 306 begins and continues to time t3, at which time the temperature reaches a peak temperature. The peak temperature may be equal to or greater than 950° C., such as equal to or greater than 1,150° C. (e.g., equal to 1,150° C. as shown in FIG. 3A). As depicted in FIG. 3A, the temperature increases from the temperature of the stabilization period 304 at time t2 to the peak temperature at time t3. The duration from time t2 to time t3 may be in a range from 3 seconds to 5 seconds. The rate of increase of the temperature may be substantially linear and may be equal to or greater than 100° C. per second, and more particularly, equal to or greater than 160° C. per second.

Once the peak temperature is reached at time t3, the cool-down period 308 begins in which the temperature is decreased, as shown in FIG. 3A. The temperature may be decreased at any rate. In the illustrated example, the decrease in temperature varies in a range from 12° C. per second to about 50° C. per second. At time t4, the flow of oxygen (O₂) gas ceases, and the nitrogen (N₂) gas flow rate is decreased to 5,000 sccm. The semiconductor substrate may then be transferred out of the process chamber.

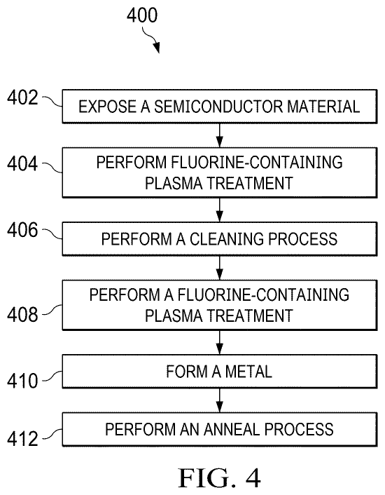

FIG. 4 is a flow chart of a method 400 for forming a metal-semiconductor compound (e.g., silicide, germanicide, etc.) according to some examples. At block 402, a semiconductor material is exposed. The semiconductor material may be, for example, silicon (Si), silicon germanium (SiGe), germanium (Ge), gallium arsenide (GaAs), gallium nitride (GaN), the like, or a combination thereof. The semiconductor material may be monocrystalline, polycrystalline, or amorphous. The semiconductor material may be included in a substrate, such as a semiconductor material of a semiconductor substrate, or may be on and/or over a substrate. Exposing the semiconductor material may include removing another material, such as a dielectric material, from the semiconductor material. For example, a dielectric layer (e.g., an oxide layer) may be on the semiconductor material, and exposing the semiconductor material includes removing, such as by etching, the dielectric layer. If the dielectric layer is an oxide layer, exposing the semiconductor material may include using an etch process, such as a wet etch, that uses hydrofluoric (HF) acid, such as a wet dilute hydrofluoric (dHF) acid.

At block 404, a fluorine-containing plasma treatment is performed on the semiconductor material. The fluorine-containing plasma treatment may be like described above with respect to block 104 in FIG. 1. The fluorine-containing plasma treatment causes fluorine to be incorporated into the semiconductor material. The fluorine-containing plasma treatment does not substantially etch the semiconductor material. At block 406, a cleaning process is performed on the semiconductor material. In some examples, the cleaning process is operable to remove any oxide that is on the semiconductor material. For example, the cleaning process may be or include a dry etch process that flows a gas combination including nitrogen trifluoride (NF₃) gas and ammonia (NH₃) gas, which etches silicon oxide. Another cleaning process may be implemented. In some examples, the cleaning process may also incorporate some fluorine into the semiconductor material. At block 408, a fluorine-containing plasma treatment is performed on the semiconductor material. The fluorine-containing plasma treatment may be like described above with respect to block 404 above and block 104 in FIG. 1. Either one or both of the fluorine-containing plasma treatments of blocks 404, 408 may be implemented in various examples.

At block 410, a metal is formed on the semiconductor material. The metal may be or include nickel (Ni), platinum (Pt), titanium (Ti), cobalt (Co), another metal, or a combination thereof. In some examples, the metal may be formed on the semiconductor material using any appropriate deposition technique, such as sputtering, physical vapor deposition (PVD), or the like. At block 412, an anneal process is performed. The anneal process causes the metal and the semiconductor material to react to form a metal-semiconductor compound (e.g., silicide, germanicide, etc.). The anneal process may be or include a rapid thermal anneal (RTA) or another anneal process.

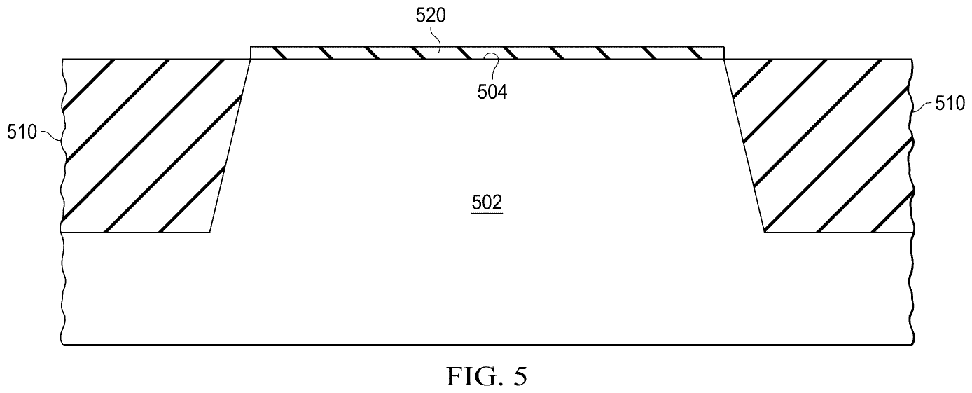

FIGS. 5 through 9 are respective cross-sectional views of a semiconductor device in intermediate stages of manufacturing according to some examples. Any of the methods 100, 200, 400 of FIGS. 1, 2, and 4 may be implemented in the context of the manufacturing of the semiconductor device in FIGS. 5 through 9. The semiconductor device manufactured according to the intermediate stages of FIGS. 5 through 9 includes a FET, and more particularly, an n-channel FET (e.g., an n-channel metal-oxide-semiconductor (NMOS) transistor). In some examples, the semiconductor device may include a p-channel FET (e.g., a p-channel metal-oxide-semiconductor (PMOS) transistor). In other examples, a different semiconductor device may be manufactured.

Referring to FIG. 5, a semiconductor substrate 502 is provided. The semiconductor substrate 502 may be or include a bulk semiconductor substrate, a semiconductor-on-insulator (SOI) substrate, or any other appropriate substrate. The semiconductor substrate 502 may also include a support (or handle) substrate and an epitaxial layer epitaxially grown on the support substrate. In some examples, the semiconductor substrate 502 is or includes a silicon substrate (which may be singulated from a bulk silicon wafer at the conclusion of semiconductor processing). In further examples, the semiconductor substrate 502 includes a silicon substrate with an epitaxial silicon layer grown thereon. The semiconductor substrate 502 is or includes a semiconductor material in and/or on which devices, such as FETs, are formed. In some examples, the semiconductor material is or includes silicon (Si), silicon germanium (SiGe), gallium arsenide (GaAs), gallium nitride (GaN), the like, or a combination thereof. The semiconductor substrate 502 has an upper surface 504 in and/or on which devices (e.g., FETs) are formed. In the illustrated example, the semiconductor material of the semiconductor substrate 502 is p-doped with a p-type dopant. In some examples, the semiconductor substrate 502 is p-doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 510 are formed in the semiconductor substrate 502. In the illustrated example, the isolation structures 510 are shallow trench isolation structures (STIs) extending from the upper surface 504 of the semiconductor substrate 502 into the semiconductor substrate 502. In the illustrated example, the isolation structures 510 may have respective upper surfaces co-planar with the upper surface 504 of the semiconductor substrate 502. In other examples, the isolation structures 510 may have respective upper surfaces above and/or may be below the upper surface 504 of the semiconductor substrate 502. The isolation structures 510 may include, for example, a liner layer, such as including silicon oxide or silicon nitride, conformally along surfaces of a respective trench in the semiconductor substrate 502 and a fill isolation material, such as silicon oxide, over and on the liner layer.

The isolation structures 510 may be formed by depositing a hardmask layer over the semiconductor substrate 502. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 502 using the patterned hardmask layer as a mask. The liner layer may then be conformally formed or deposited in the recesses or trenches and may be deposited over the patterned hardmask layer, such as by an oxidation process, plasma enhanced CVD (PECVD), or the like. The fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by the planarization process and/or an etch selective to the hardmask layer, which may be a wet etch process. In other examples, the isolation structures 510 may be field oxide structures, such as local oxidation of silicon (LOCOS) structures, at the upper surface 504 of the semiconductor substrate 502, which may be formed using a LOCOS process.

The isolation structures 510 laterally define an active area of the upper surface 504 of the semiconductor substrate 502 on which a FET is to be formed. Respective isolation structures 510 laterally encircle the active area of the upper surface 504 of the semiconductor substrate 502 on which the FET is to be formed.

For forming a p-channel FET, a well implantation may be performed. A well may be formed by the well implantation. For example, an n-type doped well may be formed. An n-type doped well may be formed by masking (e.g., by a photoresist using photolithography) areas of the semiconductor substrate 502 where an n-type doped well is not to be formed and implanting n-type dopants into the semiconductor substrate 502. An n-type doped well may extend from the upper surface 504 of the semiconductor substrate 502 into a depth in the semiconductor substrate 502, which may be to a level below, at, or above a bottom surface of the isolation structures 510. The isolation structures 510 may generally laterally define the n-type doped well. A concentration of the n-type dopant of the n-type doped well may be greater than a concentration of the p-type dopant of the p-type doped semiconductor substrate 502. In some examples, the n-type doped well may be doped with an n-type dopant (e.g., phosphorus (P) or arsenic (As)) with a concentration in a range from 1×10¹⁵ cm⁻³ to 1×10¹⁷ cm⁻³. Other doping concentrations and/or dopant type may be implemented for the doped well.

A gate dielectric layer 520 is formed over and on the semiconductor substrate 502. In the illustrated example, the gate dielectric layer 520 is formed on the upper surface 504 of the semiconductor substrate 502. The gate dielectric layer 520 is nitrided (e.g., includes nitrogen) and includes fluorine. In some examples, the gate dielectric layer 520 includes silicon oxide that is nitrided and includes fluorine.

The gate dielectric layer 520 is formed according to any of the methods 100, 200 of FIGS. 1 and 2. In the illustrated example, forming the gate dielectric layer 520 includes forming an oxide layer, such as by an oxidation process, such as ISSG oxidation like described above with respect to blocks 102, 202 of FIGS. 1 and 2. Although one FET is illustrated in the figures, different gate dielectric layers of any number of FETs may be formed on the semiconductor substrate 502. The different gate dielectric layers may have different thicknesses such that the respective FETs may have different operating voltage ratings (e.g., 1.5 V, 1.8 V, 3.3 V, 5 V, etc.). The subsequent operations of the method 100, 200 of FIGS. 1 and/or 2 may be performed on the different gate dielectric layers for the FETs. FETs with the different operating voltage ratings may also achieve advantages and benefits as described herein.

In various orders like described above, a fluorine-containing plasma treatment is performed on the gate dielectric layer 520 (e.g., gate oxide layer) to incorporate fluorine (and nitrogen as described above) into the gate dielectric layer 520, and a nitridation process is performed on the gate dielectric layer 520 to nitride and/or incorporate nitrogen into the gate dielectric layer 520. Various anneal processes may be performed, like described above with respect to FIGS. 1 and 2.

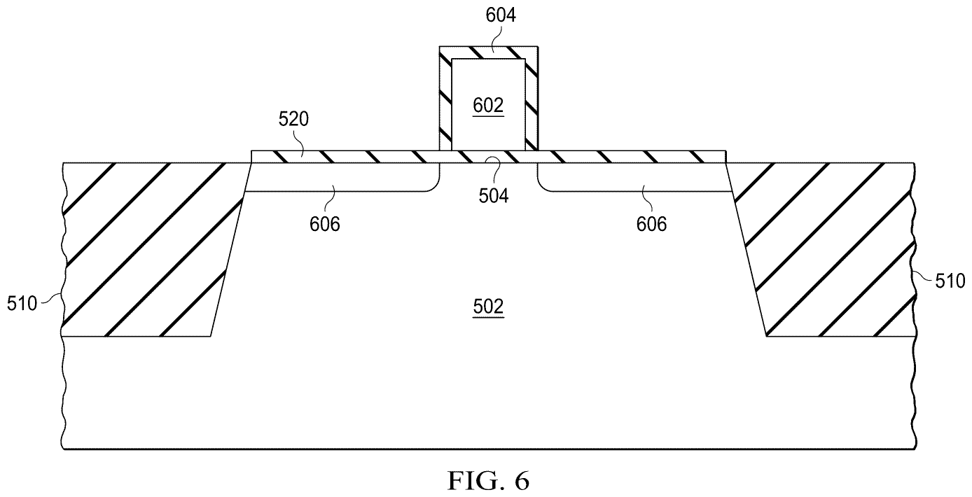

Referring to FIG. 6, a gate electrode 602 is formed over and on the gate dielectric layer 520. The gate electrode 602 may be or include any conductive material, such as a metal, a doped semiconductor material, the like, or a combination thereof. A material of the gate electrode 602 may be formed (e.g., in a layer) over the gate dielectric layer 520. The material of the gate electrode 602 may be deposited over the gate dielectric layer 520 using any deposition process, such as CVD or the like. In some examples, the gate electrode 602 is or includes a semiconductor material, such as polycrystalline silicon (polysilicon), and in such some examples, the semiconductor material may be doped in situ during deposition and/or may be implanted by a dopant after deposition (e.g., during implantation to form source/drain regions). In some examples, the gate electrode 602 is polysilicon that is p-type doped with a p-type dopant (e.g., for a p-channel FET) or is n-type doped with an n-type dopant (e.g., for an n-channel FET) with a concentration in a range from 1×10¹⁹ cm⁻³ to 1×10²¹ cm⁻³. A hardmask layer may be formed over the material of the gate electrode 602, e.g., for subsequent patterning. In some examples, the hardmask layer may be or include silicon nitride deposited by CVD, although other hardmask (e.g., dielectric) materials and/or other deposition processes may be used in other examples. The material of the gate electrode 602 may then be patterned into the gate electrode 602. In some examples, the hardmask layer is patterned corresponding to the pattern of the gate electrode 602, and using the patterned hardmask layer as a mask, the gate electrode 602 is patterned. The hardmask layer may be patterned using appropriate photolithography and etching processes, and the gate electrode 602 may be patterned using an appropriate etching process. For example, an anisotropic etch, such as an RIE, may be implemented. The hardmask layer may be removed, such as by an etch selective to the material of the hardmask layer and/or a wet strip process.

A reoxidation layer 604, as illustrated, is formed on exposed surfaces of the gate electrode 602, such as when the gate electrode 602 includes a semiconductor material (e.g., polysilicon). In some examples, the reoxidation layer 604 may be omitted. The reoxidation layer 604 may be formed by an oxidation process, such as ISSG oxidation, thermal oxidation, or another oxidation process. The reoxidation layer 604 may remove surface damage of the gate electrode 602 resulting from patterning the gate electrode 602.

Lightly doped drain (LDD) regions 606 are formed in the semiconductor substrate 502. The LDD regions 606 are formed in the semiconductor substrate 502 on laterally opposing sides of the gate electrode 602. The LDD regions 606 may be formed by masking (e.g., by a photoresist using photolithography) regions where LDD regions 606 are not to be formed and implanting a p-type dopant (e.g., for a p-channel FET) or an n-type dopant (e.g., for an n-channel FET) into the semiconductor substrate 502. The gate electrode 602 may also be implanted with the dopant and acts as a mask to prevent implantation of the dopant in at least some portions of the semiconductor substrate 502 underlying the gate electrode 602. A concentration of the p-type or n-type dopant of the LDD regions 606 may be greater than a concentration of the p-type dopant of the p-type doped semiconductor substrate 502 and, if an n-type doped well is implemented for a p-channel FET, may be greater than a concentration of the n-type dopant of the n-type doped well. In some examples, the LDD regions 606 may be doped with a p-type or n-type dopant with a concentration in a range from 1×10¹⁶ cm⁻³ to 1×10¹⁹ cm⁻³.

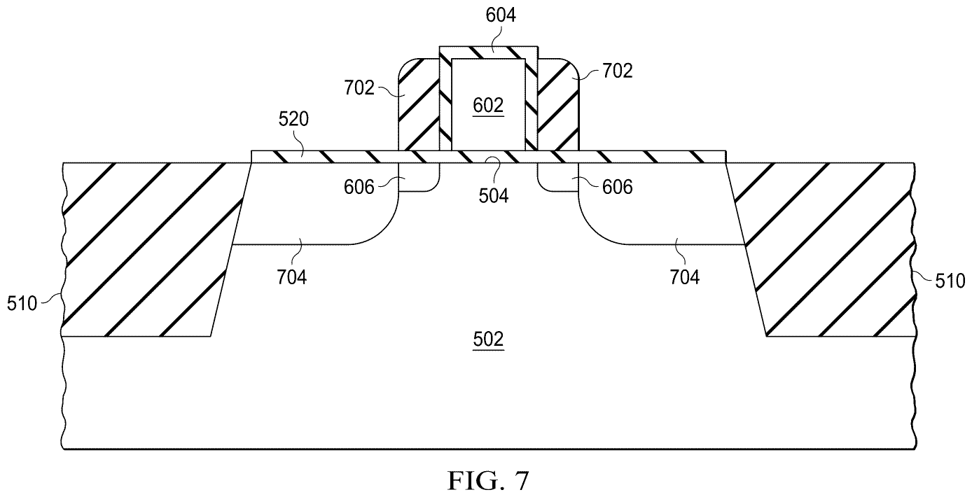

Referring to FIG. 7, gate spacers 702 are formed on or along respective sidewalls of the gate electrode 602 (e.g., on the reoxidation layer 604). The gate spacers 702 may be formed by depositing a layer of the material of the gate spacers 702 conformally over the semiconductor substrate 502 and anisotropically etching the layer such that the gate spacers 702 remain. The material of the gate spacers 702 may be or include silicon nitride, silicon oxynitride, another dielectric material, or a combination thereof. The layer may be deposited by CVD, PECVD, atomic layer deposition (ALD), or the like, and may be etched by an anisotropic etch process (e.g., RIE).

Source/drain regions 704 are formed in the semiconductor substrate 502. The source/drain regions 704 are on opposing lateral sides of the gate electrode 602 and gate spacers 702. The LDD regions 606 are between the source/drain regions 704 and underlie the respective gate spacers 702. The source/drain regions 704 may be formed by masking (e.g., by a photoresist using photolithography) regions where source/drain regions are not to be formed and implanting a p-type dopant (e.g., for a p-channel FET) or an n-type dopant (e.g., for an n-channel FET) into the semiconductor substrate 502. The gate electrode 602 and gate spacers 702 (with reoxidation layer 604 thereon) may also be implanted with the dopant and act as a mask to prevent implantation of the dopant in at least some portions of the semiconductor substrate 502 underlying the gate electrode 602 and gate spacers 702. A concentration of the p-type or n-type dopant of the source/drain regions 704 is greater than a concentration of the n-type dopant of the n-type doped well (if implemented), a concentration of the p-type or n-type dopant of the LDD regions 606, and a concentration of the p-type dopant of the p-type doped semiconductor substrate 502. In some examples, the source/drain regions 704 may be doped with a p-type or n-type dopant with a concentration in a range from 1×10¹⁹ cm⁻³ to 1×10²¹ cm⁻³.

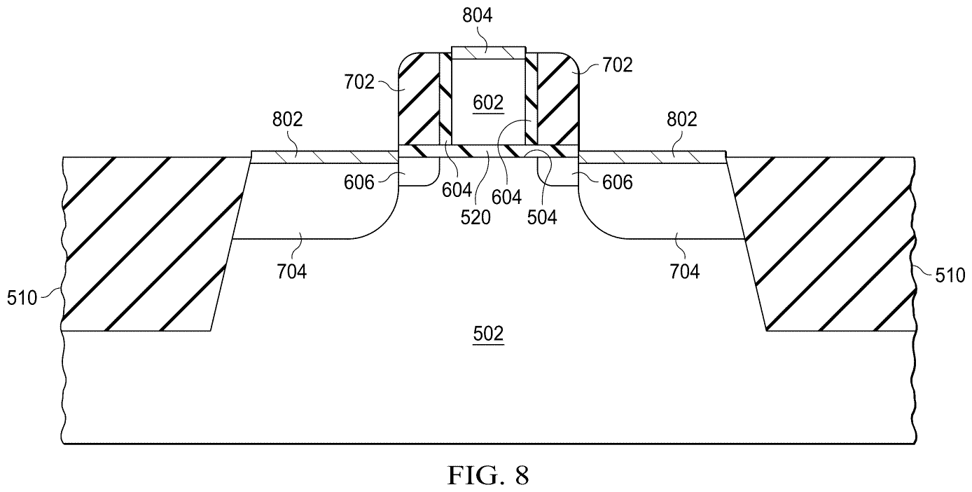

Referring to FIG. 8, metal-semiconductor compound 802 is formed on the semiconductor substrate 502 at the source/drain regions 704, and a metal-semiconductor compound 804 is formed on the gate electrode 602. The metal-semiconductor compound 804 is formed in examples in which, for example, the gate electrode 602 is or includes a semiconductor material (e.g., polysilicon). The metal-semiconductor compound 804 may be omitted in other examples. The metal-semiconductor compound 802, 804 is formed according to the method 400 of FIG. 4. The upper surface 504 of the semiconductor substrate 502 at the source/drain regions 704 and an upper surface of the gate electrode 602 are exposed per block 402 of FIG. 4. Exposing these surfaces includes removing respective portions of the gate dielectric layer 520 and the reoxidation layer 604. An etch process selective to the gate dielectric layer 520 and the reoxidation layer 604 may be used to remove these respective portions. For example, when the gate dielectric layer 520 is a silicon oxide, the respective portions of the gate dielectric layer 520 and the reoxidation layer 604 may be removed using a wet etch process that includes dilute hydrofluoric (dHF) acid. One or more fluorine-containing plasma treatments of blocks 404, 408 are performed, and a cleaning process of block 406 is performed, like described above. A metal is formed, per block 410 of FIG. 4, over the semiconductor substrate 502, and an anneal process is performed to react semiconductor to the metal per block 412. In the example of FIG. 8, the metal reacts with the semiconductor material of the semiconductor substrate 502 at the upper surface 504 at the source/drain regions 704 to form the metal-semiconductor compound 802, and the metal reacts with the semiconductor material of the gate electrode 602 to form the metal-semiconductor compound 804. Any unreacted metal may thereafter be removed, such as by an etch process selective to the metal.

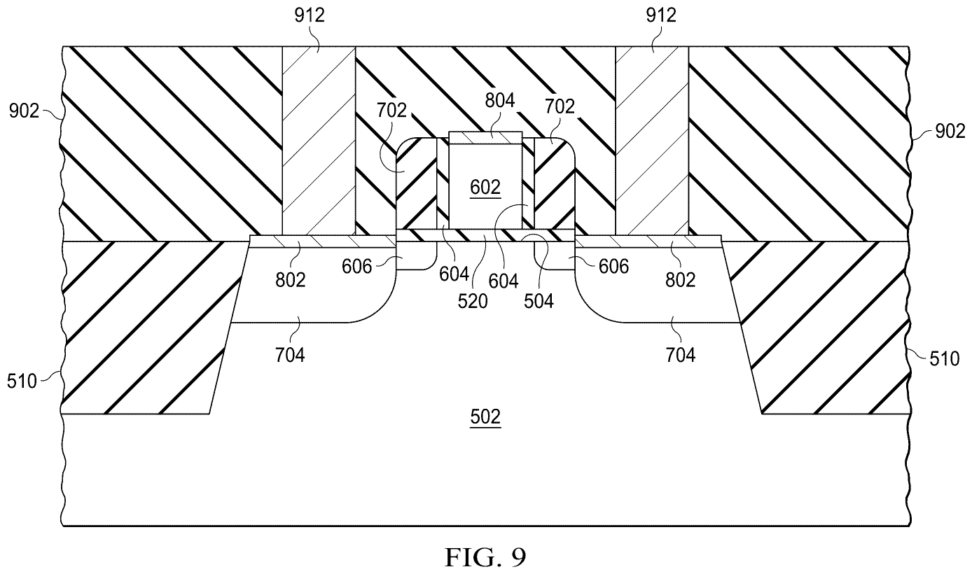

In FIG. 9, a dielectric layer 902 is formed over the semiconductor substrate 502, the gate spacers 702, and the metal-semiconductor compound 802, 804. The dielectric layer 902 may include multiple sub-layers, such as a contact etch stop layer (CESL) conformally over the semiconductor substrate 502 and a pre-metal dielectric (PMD) layer over the CESL. The CESL may be or include silicon nitride, silicon oxynitride, the like, or a combination thereof. The PMD layer may be or include silicon oxide, silicon nitride, or the like. The dielectric layer 902 may be deposited using CVD, PECVD, ALD, or the like. The dielectric layer 902 may be planarized, such as by a CMP process.

Contacts 912 are formed to the metal-semiconductor compound 802 on the source/drain regions 704. The contacts 912 extend through the dielectric layer 902 and contact respective metal-semiconductor compound 802 on the source/drain regions 704. The contacts 912 may each include one or more barrier and/or adhesion layers (e.g., titanium nitride (TiN), tantalum nitride (TaN), the like, or a combination thereof) conformally in a respective opening through the dielectric layer 902, and a fill metal (e.g., tungsten (W), copper (Cu), aluminum (Al), the like, or a combination thereof) over and/or on the barrier and/or adhesion layer(s).

To form the contacts 912, respective openings may be formed through the dielectric layer 902 to the metal-semiconductor compound 802 using appropriate photolithography and etching processes. A metal(s) of the contacts 912 are deposited in the openings through the dielectric layer 902. The metal(s) may be deposited using an appropriate deposition process(es), such as CVD, PVD, or the like. Any excess metal(s) may be removed, such as by a CMP and/or by patterning using photolithography and etch processes. Subsequent back-end-of-the-line (BEOL) processing may thereafter be performed.

As illustrated by FIG. 9, a FET includes the gate electrode 602, the gate dielectric layer 520 underlying the gate electrode 602, the source/drain regions 704 in the semiconductor substrate 502, LDD regions 606 in the semiconductor substrate 502, and a channel region in the semiconductor substrate 502. The channel region underlies (e.g., directly underlies) the gate electrode 602 and the gate dielectric layer 520. The channel region is between the LDD regions 606 and is between the source/drain regions 704. One LDD region 606 is between the channel region and a corresponding source/drain region 704, and the other LDD region 606 is between the channel region and the other source/drain region 704. The gate spacers 702 are along respective sidewalls of the gate electrode 602. If the FET is an n-channel FET, the source/drain regions 704 and LDD regions 606 may be n-type doped. If the FET is a p-channel FET, the source/drain regions 704 and LDD regions 606 may be p-type doped, and the p-channel FET may further include an n-type doped well in the semiconductor substrate 502, where the source/drain regions 704 and LDD regions 606 are in the n-type doped well.

Using any of the methods 100, 200 of FIGS. 1 and 2 in forming the FET illustrated in FIG. 9 causes the gate dielectric layer 520 to be nitrided (e.g., include nitrogen) and fluorinated (e.g., include fluorine). The fluorine may be incorporated into the gate dielectric layer 520 in a controlled manner. In some examples, fluorine is not implanted by an implantation process into the gate dielectric layer 520 and into the gate electrode 602. The fluorine-containing plasma treatment may permit fluorine to diffuse into the gate dielectric layer 520 to a shallow depth, such as 22 Angstroms or less. Accordingly, fluorine may not be in the semiconductor substrate 502 at significant depths. Further, since the fluorine is incorporated into the gate dielectric layer 520 before the gate electrode 602 is formed and the gate electrode 602 is not implanted with fluorine, in some examples, the gate electrode 602 does not include fluorine at least in a portion proximate the gate dielectric layer 520. In some examples, due to formation of the metal-semiconductor compound 804 as described above, another portion of the gate electrode 602 at the metal-semiconductor compound 804 may include fluorine.

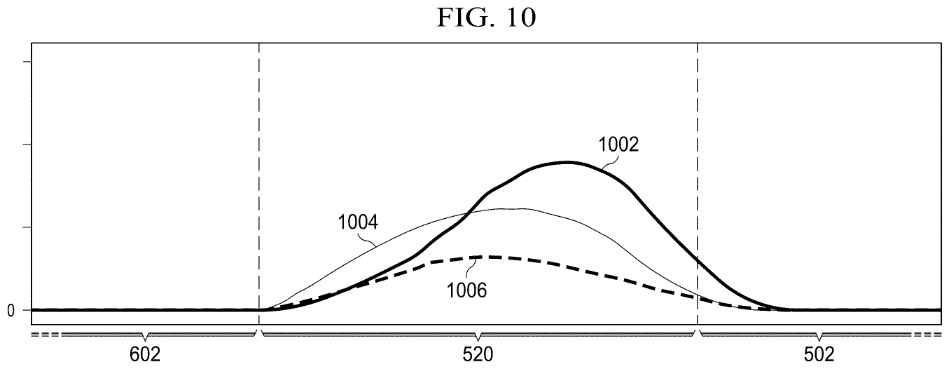

FIG. 10 is a graph illustrating fluorine profiles 1002, 1004, 1006 across the gate electrode 602, the gate dielectric layer 520, and the semiconductor substrate 502 according to some examples. As illustrated, no significant amount of fluorine (e.g., no fluorine) is in a portion of the gate electrode 602 proximate to the gate dielectric layer 520 for any of the fluorine profiles 1002, 1004, 1006. The concentrations of fluorine peak in the gate dielectric layer 520 for each of the fluorine profiles 1002, 1004, 1006. Some fluorine is present in the semiconductor substrate 502 at an interface between the gate dielectric layer 520 and the semiconductor substrate 502 for each of the fluorine profiles 1002, 1004, 1006. The concentration of fluorine decreases to no significant amount (e.g., no fluorine) at a relatively shallow depth in the semiconductor substrate 502 from the interface (e.g., no deeper than a depth of 15 Angstroms from the interface). In some examples, the gate dielectric layer 520 may have a concentration of fluorine of 29 atomic % and a concentration of nitrogen of 19 atomic %.

By incorporating fluorine using a fluorine-containing plasma as described, fluorine may be incorporated in a more controlled manner which permits reduction of a thickness of the gate dielectric layer 520. Further, with the reduced thickness of the gate dielectric layer 520, the fluorine-containing plasma treatment may permit nitridation of the gate dielectric layer 520 to occur based on the molecular nitridation, which may reduce diffusion of nitrogen into the semiconductor substrate 502. Reducing diffusion of nitrogen into the semiconductor substrate 502 may reduce a fixed charge caused by nitrogen that may be undesirable for reliability characteristics of an FET. Fluorine may improve a quality of an interface between the gate dielectric layer 520 (e.g., gate oxide layer) and the semiconductor substrate 502. Fluorine may fill vacancies and defects at the interface to improve the quality. Improving the interface may improve mobility of carriers in the channel region of the FET. By reducing the fixed charge and improving mobility of carriers in the channel region, doping in the channel region may be reduced, which may permit variability in electrical characteristics of FETs to be decreased such that performance mismatch between FETs and noise may be reduced.

In experiments, improvement in performance of NMOS transistors was observed. Drain-to-source on current (I_{DS}) versus drain-to-source off current (I_{OFF}) for core NMOS transistors was improved by approximately 12%. Further, improvement in I_{DS}-I_{OFF} for 1.8 V input/output (IO) NMOS transistors and PMOS transistors was observed. Drain induced barrier lowering (DIBL) of core NMOS transistors was reduced by approximately 6%.

Using the method 400 of FIG. 4 to form the metal-semiconductor compound 802 incorporates fluorine in the metal-semiconductor compound 802 and in the semiconductor substrate 502 at the upper surface 504 where the metal-semiconductor compound 802 is formed. A concentration of the fluorine may decrease (e.g., quickly decrease) from an interface between the metal-semiconductor compound 802 and the semiconductor substrate 502 into a depth in the semiconductor substrate 502. The fluorine may interact with defects (e.g., silicon interstitials) in the semiconductor substrate 502 which may reduce metal piping into the semiconductor substrate 502. Metal piping, such as by nickel, into the semiconductor substrate 502 may cross a p-n junction in the semiconductor substrate 502 to adversely affect the FET in which the metal piping occurs. Reducing the metal piping may therefore improve operations and reliability of FETs. Similarly, using the method 400 of FIG. 4 to form the metal-semiconductor compound 804 incorporates fluorine in the metal-semiconductor compound 804 and in an upper portion of the gate electrode 602 where the metal-semiconductor compound 804 is formed. A concentration of the fluorine may decrease (e.g., quickly decrease) from an interface between the metal-semiconductor compound 804 and the gate electrode 602 into a depth in the gate electrode 602.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a gate dielectric layer over the semiconductor substrate, the gate dielectric layer including nitrided silicon oxide that includes fluorine; and
a gate electrode over the gate dielectric layer, the gate electrode including a first portion proximate the gate dielectric layer, the first portion not including fluorine.

2. The semiconductor device of claim 1, wherein the semiconductor substrate includes fluorine at an interface between the semiconductor substrate and the gate dielectric layer.

3. The semiconductor device of claim 1, further comprising a first source/drain region and a second source/drain region in the semiconductor substrate, the first source/drain region being on a laterally opposing side of the gate electrode from the second source/drain region.

4. The semiconductor device of claim 3, further comprising a metal-semiconductor compound on the semiconductor substrate at the first source/drain region, the metal-semiconductor compound including fluorine.

5. The semiconductor device of claim 4, wherein the metal-semiconductor compound includes a silicide including nickel.

6. The semiconductor device of claim 1, further comprising a metal-semiconductor compound on the gate electrode, the gate electrode including polycrystalline silicon, the gate electrode including a second portion at the metal-semiconductor compound, the metal-semiconductor compound including fluorine.

7. A method, comprising:
forming an oxide layer over a semiconductor substrate;
performing a fluorine-containing plasma treatment on the oxide layer; and
nitriding the oxide layer.

8. The method of claim 7, wherein performing the fluorine-containing plasma treatment is before nitriding the oxide layer.

9. The method of claim 7, wherein nitriding the oxide layer is before performing the fluorine-containing plasma treatment.

10. The method of claim 7, further comprising performing an anneal process after performing the fluorine-containing plasma treatment and nitriding the oxide layer.

11. The method of claim 7, wherein the fluorine-containing plasma treatment is performed with a pressure of equal to or greater than 50 milliTorr.

12. The method of claim 7, wherein the fluorine-containing plasma treatment is performed with a source power of equal to or less than 300 Watts.

13. The method of claim 7, wherein the fluorine-containing plasma treatment includes flowing a gas mixture including nitrogen trifluoride (NF₃) gas, dinitrogen hexafluoride (N₂F₆) gas, or a combination thereof.

14. The method of claim 7, wherein the fluorine-containing plasma treatment includes:
flowing a fluorine-containing gas at a rate in a range from 5 standard cubic centimeters per minute (sccm) to 15 sccm;
flowing an inert gas at a rate in a range from 100 sccm to 200 sccm;
a pressure in a range from 50 milliTorr to 300 milliTorr; and
a source power equal to or less than 100 Watts.

15. The method of claim 7, further comprising forming a gate electrode over the oxide layer after performing the fluorine-containing plasma treatment and nitriding the oxide layer.

16. A method, comprising:
forming a gate oxide layer over a semiconductor substrate;
incorporating fluorine into the gate oxide layer including using a plasma treatment;
nitriding the gate oxide layer; and
forming a gate electrode over the gate oxide layer.

17. The method of claim 16, wherein the plasma treatment is performed before nitriding the gate oxide layer.

18. The method of claim 16, wherein nitriding the gate oxide layer is performed before the plasma treatment.

19. The method of claim 16, further comprising annealing the gate oxide layer after the plasma treatment and nitriding the gate oxide layer.

20. The method of claim 16, wherein the plasma treatment includes flowing a fluorine-containing gas.

21. The method of claim 16, wherein the plasma treatment uses a source power equal to or less than 300 Watts and a pressure equal to or greater than 50 milliTorr.
